(19) United States
(12) Patent Application Publication
(10) Pub. No.: US 2010/0091829 A1
(43) Pub. Date: Apr. 15, 2010

(54) OPTIMISED ARCHITECTURE FOR A DOWNSAMPLING FIR FILTER

(75) Inventors: Ludwig Schwoerer, Hattingen (DE); Gerald Beier, Dortmund (DE)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/593,361

(22) PCT Filed: Mar. 28, 2007
(86) PCT No.: PCT/IB2007/051096

§ 371 Date: Sep. 28, 2009

(51) Int. Cl. H03K 5/159

(52) U.S. Cl. 375/229

(57) ABSTRACT

An apparatus for generating filtered and downsampled data comprises a calculation unit, a polyphase addition unit and a downsampling unit operable in a data decimation phase and a data preserving phase. The calculation unit is arranged to receive input data and is configured to generate a first data part during the data decimation phase and a second part during the data preserving phase. The polyphase addition unit is configured to generate a third data part in dependence on said first and second data parts and to output said third data part to the downsampling unit.

### FIELD OF THE INVENTION

The invention relates to a downsampling finite impulse response (FIR) filter. In particular, the invention relates to an optimised architecture for a downsampling FIR filter which could be used in, but is not limited to, digital front-end filtering in a mobile telecommunications apparatus.

### BACKGROUND OF THE INVENTION

Downsampling FIR filters are an important component for many digital signal-processing applications.

However, frequently the downsampling process results in inefficient operation due to the performance of redundant operations. Redundant operations may also be performed when the underlying ‘base’ filter has degenerate coefficients. In particular, redundant operations may be performed if the filter coefficients are symmetric.

The performance of redundant operations leads to an unnecessarily large power requirement. This is sub-optimal.

Furthermore it is desirable to reduce the number of components in downsampling FIR filters in order to reduce the apparatus size. However, previous FIR filters have not exploited the downsampling process or the coefficient degeneracy or symmetry in order to minimize the number of components.

FIG. 1 shows a diagram of a basic downsampling FIR filter. The filter comprises a shift-register 1, a calculation unit 2 comprising a plurality of multipliers, an adder 3, means for receiving a clock signal 4 and a downsampling unit 5. In this case the downsampling is performed with a decimation factor of two.

The shift register 1 receives an input data stream and provides a data part to the calculation unit 2 every clock cycle. The multipliers each multiply a portion of the data part with a coefficient of the filter. The adder 3 sums the output of the multipliers. Just before the downsampling unit 5, the output of the filter is given by

yₙ=C₁xₙ+C₂xdₙ₋₁+C₃xₙ₋₂+C₄xₙ₋₃+C₅xₙ₋₄+C₆xₙ₋₅

where xₙ is the input signal, yₙ is the signal just before the downsampling unit, and C₁, C₂, . . . , Cₙ are the filter coefficients. The downsampling unit 5 decimates every second input which it receives. Thus, the downsampling unit is operable in a data decimation phase, in which received data will be decimated, and in a data preserving phase, in which received data will not be decimated. All of the multiplication and addition operations performed during the data decimation phase are redundant, since the calculated data sent to the downsampling unit during this phase is discarded.

FIGS. 2 and 3 show examples of downsampling FIR filters in which the FIR filter has symmetric coefficients and the symmetry of the coordinates is exploited. FIG. 2 shows an example in which there are an even number of coefficients, and FIG. 3 shows an example in which there are an odd number of coefficients.

For the filter shown in FIG. 2, C4=C5, C6=C3 and C7=C2. That is, some of the coefficients are degenerate. The filter comprises a calculation unit 2 having multipliers 6 and adders 7. Instead of multiplying each data portion by a coefficient, coefficients to be multiplied by degenerate coefficients are summed in an adder 7 before being multiplied in a multiplier 6. Thus, the number of multipliers and the number of multiplication operations is reduced. However, as with the filter of FIG. 1, all of the addition and multiplication operations which occur during the data decimation phase are redundant. Furthermore, the data flow is handled in an inefficient way.

### SUMMARY OF THE INVENTION

The present invention provides an apparatus comprising a calculation unit, a polyphase addition unit and a downsampling unit operable in a data decimation phase and a data preserving phase, wherein the calculation unit is arranged to receive input data and is configured to generate a first data part during the data decimation phase and a second part during the data preserving phase; and the polyphase addition unit is configured to generate a third data part in dependence on said first and second data parts and to output said third data part to the downsampling unit such that the apparatus generates filtered and downsampled data.

The calculation unit may comprise a multiplier and the apparatus may be configured so that the multiplier receives a first multiplier coefficient during the data decimation phase and a second multiplier coefficient during the data preserving phase and the calculation unit may be configured to generate the first and second data parts in dependence on the first and second multiplier coefficients respectively.

The apparatus may further comprise a plurality of multipliers, and each multiplier may serially receive its own sequence of multiplier coefficients and the multiplier coefficients received may be the coefficients of a predetermined linear function.

The plurality of multipliers may alternately receive even and odd coefficients of the predetermined linear function.

The apparatus may be arranged so that the number of different coefficients received by each multiplier is equal to the downsampling factor of the downsampling unit.

The apparatus may further comprise an adder, and the polyphase addition unit may comprise a plurality of polyphase addition sub-units and may be configured to receive data from the calculation unit and output data to the downsampling unit and the downsampling unit may comprise a plurality of downsampling sub-units and the adder may be configured to calculate the sum of the outputs of the downsampling sub-units.

The calculation unit may comprise an adder and a plurality of multipliers and the adder may be configured to calculate the sum of the outputs of the multipliers and to output the sum to the polyphase addition unit.

The calculation unit may be configured to receive an input data part during a time interval and to multiply a portion of the input data part by a predetermined coefficient.

The calculation unit may receive an input data part during a time interval and the apparatus may be configured to calculate a linear function of the input data part.

The calculation unit may comprise an adder, and the received input data part may have a first data portion and a second data portion and the linear function may have first and second degenerate coefficients and the calculation unit may calculate the sum of the product of the first data portion and the first degenerate coefficient and the product of the second data portion and the second degenerate coefficient by summing the first and second data portions in the adder and multiplying the output of the adder by the value of the degenerate coefficient.

The apparatus may further comprise means for receiving a clock signal and the time interval may be a clock cycle.

The apparatus may further comprise a shift register, and the shift register may receive an input data stream and a clock signal and the calculation unit may receive data from the shift register.

The calculation unit may further comprise a data direction unit and the data direction unit may be configured to receive a plurality of data parts and a control signal and to generate output data in dependence on the control signal and on a received data part.

The calculation unit may have a calculation sub-unit and the calculation sub-unit may receive data from the data direction unit.

The data direction unit may be a multiplexer.

The data direction unit may be a re-ordering block.

The re-ordering block may receive a plurality of data parts in a first order and may be configured to output said plurality of data parts in a second order.

The re-ordering block may comprise one or more registers and one or more multiplexers configured to receive the control signal.

The polyphase addition unit may comprise a register and an adder.

The polyphase addition unit may be arranged to calculate and store a cumulative sum of n received inputs, where n is the downsampling factor of the downsampling unit.

The polyphase addition unit may further comprise a multiplexer, and the multiplexer may reset the stored cumulative sum to 0 after the cumulative sum of n inputs has been calculated.

The apparatus may implement a downsampling finite impulse response filter.

According to the invention, there is provided a method comprising generating filtered and downsampled data by receiving input data generating a first data part during a first time interval and a second element during a second time interval and generating an output data stream in dependence on said first and second data parts; and downsampling the output data stream.

The method may further comprise steps of receiving a first multiplier coefficient during a first time interval and a second multiplier coefficient during a second time interval and generating the first and second data parts in dependence on the first and second multiplier coefficients respectively.

The method may further comprise a step of serially receiving a sequence of coefficients.

The method may further comprise steps of receiving an input data part during a time interval and multiplying a portion of the input data part by a predetermined coefficient.

The calculation unit may receive an input data part during a time interval and the method may calculate a linear function of the input data part.

The linear function may have first and second degenerate coefficients and the method may calculate the sum of the products of the first data portion and the first degenerate coefficient and the second data portion and the second degenerate coefficient by adding the first and second data portion and multiplying the result by the value of the degenerate coefficient.

The method may further comprise directing data in dependence on a control signal. The method may further comprise re-ordering data.

The method may implement a downsampling finite impulse response filter.

### BRIEF DESCRIPTION OF THE DRAWINGS

Embodiments of the present invention will now be described, by way of example only, with reference to the accompanying drawings in which:

FIG. 1 shows a basic downsampling FIR filter configuration;

FIG. 2 shows a downsampling FIR filter configuration with an even number of taps in which the symmetry of the coefficients is exploited;

FIG. 3 shows a further downsampling FIR filter configuration with an odd number of taps in which the symmetry of the coefficients is exploited;

FIG. 4 shows a downsampling FIR filter configuration for downsampling by a factor of 2 which uses polyphase addition and in which the number of multiplication operations is minimized;

FIG. 5 shows a general polyphase addition configuration;

FIG. 6 shows a downsampling FIR filter configuration for downsampling by a factor of n which uses polyphase addition and in which the number of multiplication operations is minimized;

FIG. 7 shows a downsampling FIR filter configuration in which the adder and register usage is minimised by using only one single polyphase adder after the summation of the multiplication results;

FIG. 8 shows a downsampling FIR filter configuration with an even number of coefficients for downsampling by a factor of 2 which includes a re-ordering block; and

FIG. 9 shows a downsampling FIR filter configuration with an odd number of coefficients for downsampling by a factor of 2 which includes a re-ordering block.

### DETAILED DESCRIPTION

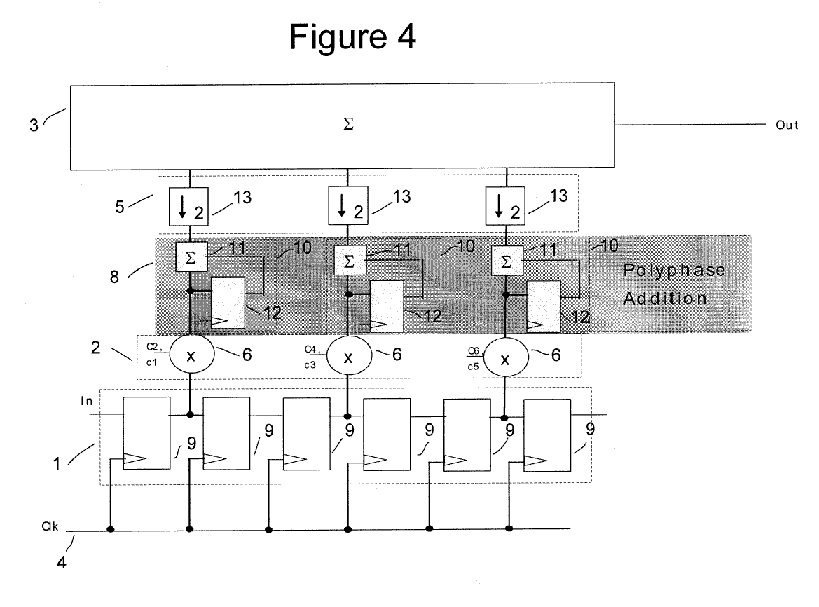

Referring to FIG. 4, a downsampling FIR filter comprises a shift register 1, a calculation unit 2, a polyphase addition unit 8 and a downsampling unit 5. The shift register 1 receives an input data stream and a clock signal and comprises a plurality of registers 9. The calculation unit 2 comprises a plurality of multipliers 6. The polyphase addition unit 8 comprises a plurality of polyphase addition sub-units 10. Each polyphase addition sub-unit 10 comprises an adder 11 and a register 12. The downsampling unit 5 comprises a plurality of downsampling sub-units 13.

The shift register 1 receives an input data stream and provides a data part to the multipliers 6. The multipliers 6 each multiply a portion of the data part by a coefficient. Each polyphase addition sub-unit 10 generates an output which is the sum of the input to the polyphase addition sub-unit at a particular clock cycle and the input to the polyphase addition unit at the previous clock cycle. Thus, the polyphase addition sub-units 10 combine the output of the multiplier over two consecutive clock cycles. The output of the each polyphase addition sub-unit is downsampled by a factor of two in a downsampling sub-unit 13. The adder 3 then sums the output of the downsampling sub-units, hence generating the output.

Two of the original coefficients are alternatingly given to the multipliers 6: In a first phase all even ones, and in a second phase all odd ones.

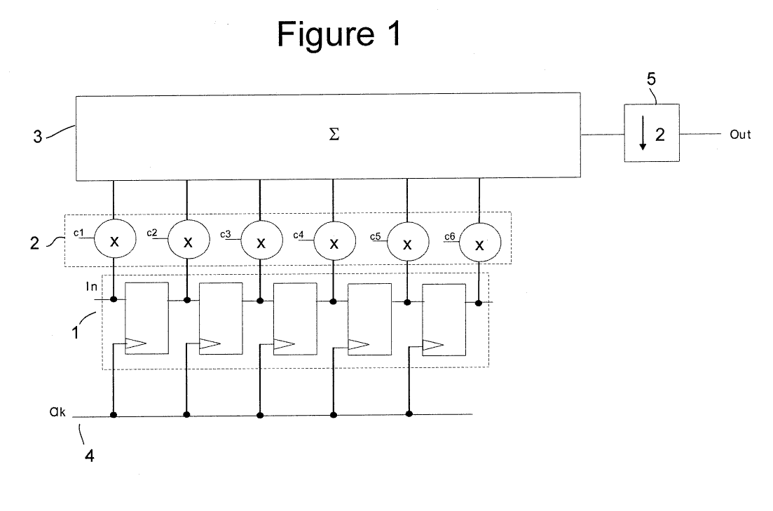

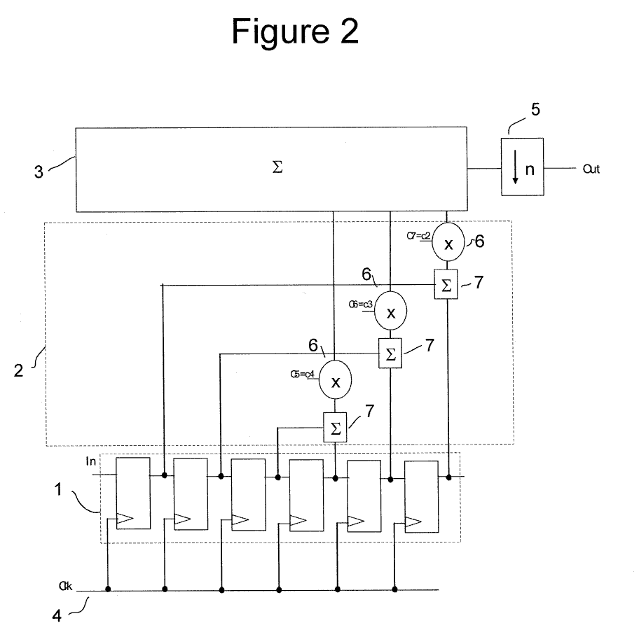

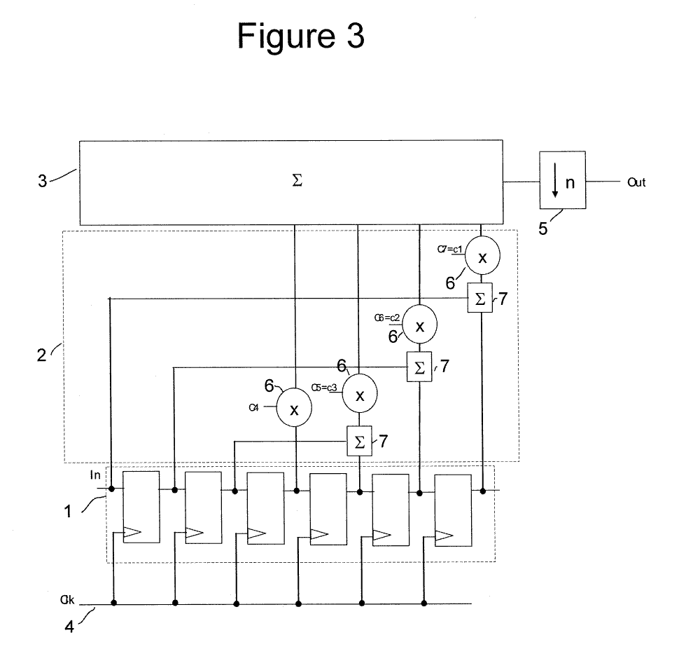

Thus, the structure generates the same output as the structure of FIG. 1, but the number of multipliers and is reduced and the number of operations is reduced. Furthermore, all operations used in all clock cycles contribute to the output.

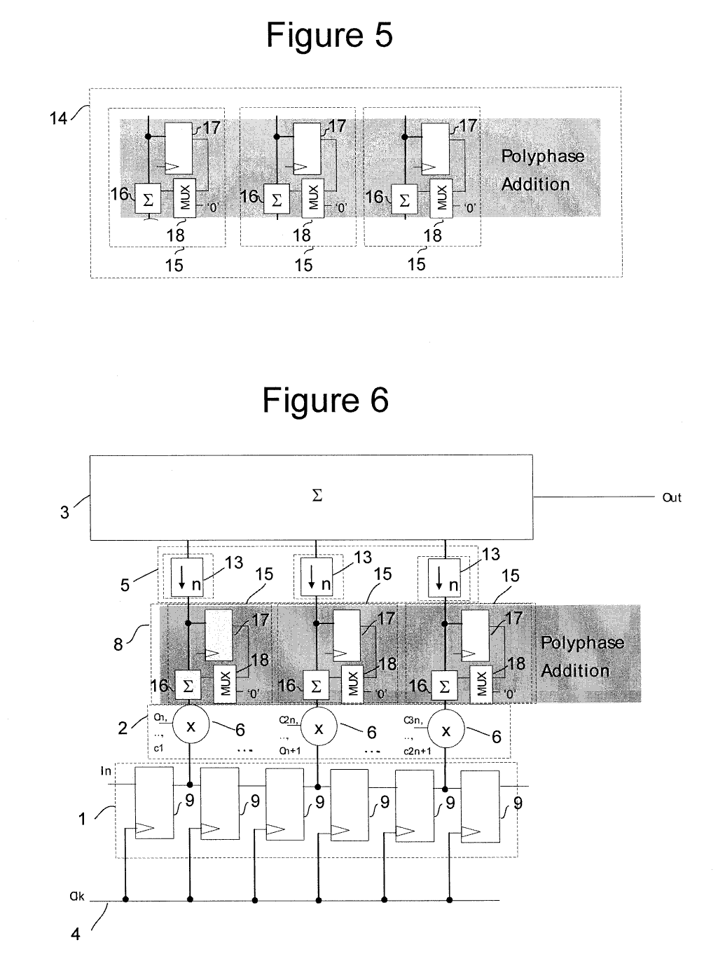

FIG. 5 shows a generalised polyphase addition unit 14 which comprises a plurality of polyphase addition sub-units 15. Each polyphase addition sub-unit 15 comprises an adder 16, a register 17 and a multiplexer 18. Each polyphase addition sub unit 15 sums its input over n clock cycles and after n inputs are accumulated, the final sums are output. With the start of a new run through the n phases, the cumulative sum stored in the polyphase addition sub-unit is reset to zero by injecting a zero into the adder 16 using the multiplexer 18.

FIG. 6 shows a further downsampling FIR filter, which is a downsampling FIR filter for downsampling by a factor of n. Here, the original sequence of coefficients is subdivided into n (the downsampling factor) subsets, which are serially given to the multipliers. In the polyphase addition sub units, the outputs of the multipliers are summed over n clock cycles and after n outputs are accumulated, the final sums are given to the final adder. With the start of a new run through the n phases, the cumulative sum stored in the polyphase addition sub-unit is reset to zero using a multiplexer.

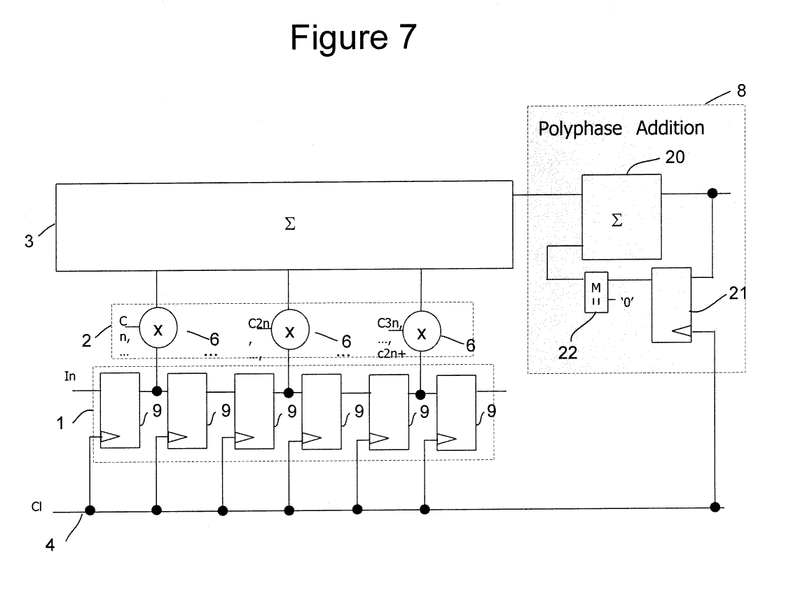

FIG. 7 shows a further optimised form of the filter of FIG. 6 in which the outputs of the multipliers 6 are summed in the adder 3 and output to the polyphase addition unit 8. The polyphase addition unit comprises an adder 20, a register 21 and a multiplexer 22. The output of the polyphase addition unit is then downsampled by the downsampling unit (not shown). Thus, instead of having an adder in each branch for the partial products, the polyphase addition is shifted behind the adder. This results in having one adder with the sum wordlength instead of having several adders with the wordlength of the partial products (plus extension). Also the number of registers for storing the partial product sums is reduced over the previous embodiment. For example, for a 10 bit partial product, a downsampling ratio of 4 and a filter with 16 coefficients the previous embodiment requires 4 12 bit adders and registers according to FIG. 6. In the present embodiment, this is reduced to one 14 bit adder and one 14 bit wide register.

In general the following equation holds for the total summation wordlength:

n+┌log₂(m)┐+┌log₂(d)┐<m(n+┌log₂(d)┐)

Where n is the wordlength of the partial products, m is the number of coefficients divided by the decimation ratio and d is the decimation ratio.

Therefore, compared to previous embodiments, the number of adders and registers in the present embodiment is reduced. This may be advantageous in terms of area power and cost, for example. The minimization can be implemented regardless of how the polyphase addition is achieved.

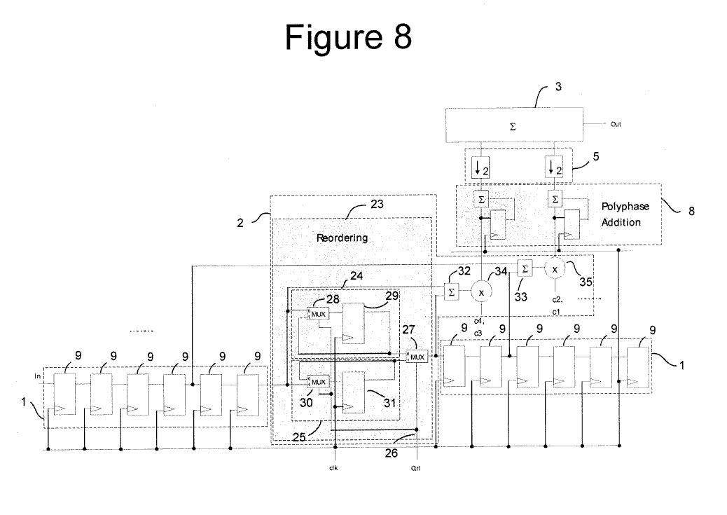

FIG. 8 shows a further exemplary embodiment of an FIR filter in which the number of coefficients is even and the filter decimates by a factor of 2. In this arrangement, the calculation unit 2 comprises a re-ordering block 23. The re-ordering block may be configured to receive a plurality of data portions in a first order and to output a plurality of data portions in a second order. The re-ordering block comprises a first memory part 24 and a second memory part 25, means for receiving a control signal 26, and an output multiplexer 27. Each memory part comprises a multiplexer 28, 30 and a register 29, 31. The re-ordering unit receives a data portion and may store the data portion in the first memory part 24 or the second memory part 25 in dependence on the control signal. The re-ordering unit may output a data portion from the first memory or the second memory in dependence on the control signal. Thus, the re-ordering unit may re-order data.

In the first memory part 24 the multiplexer 28 may receive a first multiplexer input data portion from the output of a register 9 of the shift register 1 and a second multiplexer input data portion from the output of a register 29 of the first memory part 24 of the re-ordering unit 29. The multiplexer 28 outputs either the first multiplexer input data portion or the second multiplexer input data portion to the input of the register 29 in dependence on the control signal. If the control signal is ‘0’ the input multiplexer 28 may output the output of the register 29 to the input of the register 29. If the control signal is a ‘1’ the input multiplexer 28 may output the output of a register 9 of the shift register 1 to the input of the register 29.

In the second memory part 25 the multiplexer 30 may receive a first multiplexer input data portion from the output of a register 9 of the shift register 1 and a second multiplexer input data portion from the output of a register 31 of the second memory part 25 of the re-ordering unit 29. The multiplexer 30 outputs either the first multiplexer input data portion or the second multiplexer input data portion to the input of the register 31 in dependence on the control signal. If the control signal is ‘1’ the input multiplexer 30 may output the output of the register 31 to the input of the register 31. If the control signal is a ‘0’ the input multiplexer 30 may output the output of a register 9 of the shift register 1 to the input of the register 31.

The output multiplexer 27 may output the data stored in either the first memory part 24 or the second memory part 25 to a register 9 of the shift register 1.

Thus, the re-ordering unit may re-order data. In particular, the re-ordering block may re-order data so that any two samples that are received by the re-ordering block are output by the re-ordering block in reverse order.

The adder 32 may receive data from the re-ordering block. Furthermore, the adder, 33, may receive data which has been re-ordered by the re-ordering block. Thus, the adders 32, 33, may receive data in dependence on the control signal. The multipliers 34, 35 may receive data from the adders 32, 33. Thus, the multiplier may receive data in dependence on the control signal. Thus, according to the invention, the structure may comprise calculation sub-units which receive data in dependence on the control signal.

The re-ordering block enables the addition of (delayed) input samples that are to be multiplied with the same coefficient.

The re-ordering block may allow a reduction in the number of multipliers. Furthermore, the re-ordering block may allow the dataflow to be handled in an efficient way.

The addition of (delayed) input samples may also be achieved by using multiplexing circuitry for every element in the later part of the delay chain.

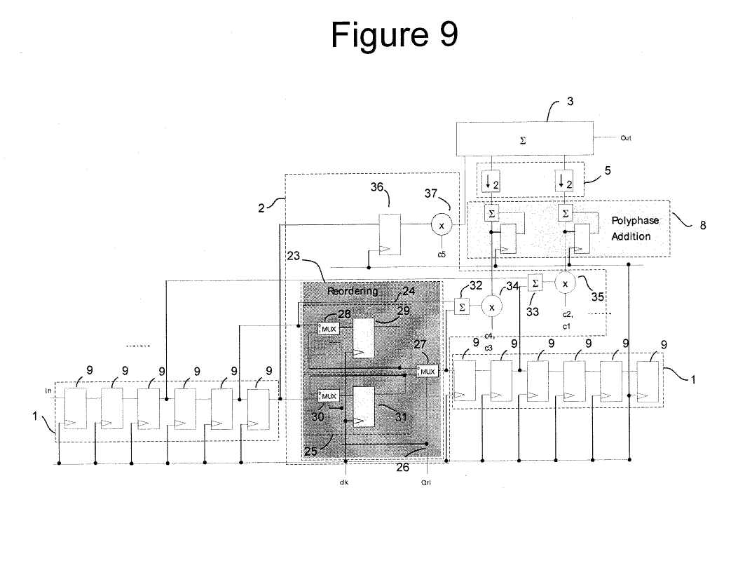

FIG. 9 shows a further embodiment of an FIR filter in which the number of coefficients is odd and the filter decimates by a factor of 2. The structure further comprises a register 36 and a multiplier 37. Thus, an FIR filter according to this example may comprise further registers and multipliers if the number of coefficients is odd.

For downsampling factors other than two, the re-ordering may be generalised in such a way that any group of n samples that is taken into the re-ordering block may be output by the re-ordering block in reverse order. For example, for a downsampling factor of 4, the re-ordering block may take in 4 samples (1 2 3 4) and may produce an output of (4 3 2 1)

The above described embodiments and alternatives may be used either singly or in combination to achieve the effects provided by the invention.

Many other modifications and variations will be evident to those skilled in the art, that fall within the scope of the following claims:

1. An apparatus comprising:
a calculation unit;
a polyphase addition unit; and
a downsampling unit operable in a data decimation phase and a data preserving phase;
wherein the calculation unit is configured to receive input data and is configured to generate a first data part during the data decimation phase and a second data part during the data preserving phase; and
the polyphase addition unit is configured to generate a third data part in dependence on said first and second data parts and to output said third data part to the downsampling unit,
such that the apparatus generates filtered and downsampled data.

2-31. (canceled)

32. The apparatus of claim 1, wherein the calculation unit comprises a multiplier configured to receive a first multiplier coefficient during the data decimation phase and a second multiplier coefficient during the data preserving phase; and the calculation unit is configured to generate the first and second data parts in dependence on the first and second multiplier coefficients respectively.

33. The apparatus of claim 32, further comprising a plurality of multipliers, wherein each of the plurality of multipliers serially receives its own sequence of multiplier coefficients; and wherein the multiplier coefficients received are coefficients of a predetermined linear function.

34. The apparatus of claim 33, wherein at least one of the plurality of multipliers alternately receives even and odd coefficients of the predetermined linear function.

35. The apparatus of claim 33, wherein the number of different coefficients received by each multiplier is equal to the downsampling factor of the downsampling unit.

36. The apparatus of claim 1, further comprising an adder, wherein the polyphase addition unit comprises a plurality of polyphase addition sub-units and is configured to receive data from the calculation unit and output data to the downsampling unit; and the downsampling unit comprises a plurality of downsampling sub-units and the adder is configured to calculate the sum of the outputs of the downsampling sub-units.

37. The apparatus of claim 32, wherein the calculation unit comprises an adder and a plurality of multipliers and the adder is configured to calculate the sum of the outputs of the multipliers and to output the sum to the polyphase addition unit.

38. The apparatus of claim 1, wherein the calculation unit is configured to receive an input data part during a time interval and to multiply a portion of the input data part by a predetermined coefficient.

39. The apparatus of claim 1, wherein the calculation unit is configured to receive an input data part during a time interval and to calculate a linear function of the input data part.

40. The apparatus of claim 39, wherein the calculation unit comprises an adder, and the received input data part has a first data portion and a second data portion; and the linear function has first and second degenerate coefficients; and the calculation unit calculates the sum of the product of the first data portion and the first degenerate coefficient and the product of the second data portion and the second degenerate coefficient by summing the first and second data portions in the adder and multiplying the output of the adder by the value of the degenerate coefficient.

41. A method, comprising:
generating filtered and downsampled data from received input data;
generating a first data part during a first time interval and a second data part during a second time interval;
generating an output data stream in dependence on said first and second data parts; and
downsampling the output data stream.

42. The method of claim 41, further comprising receiving a first multiplier coefficient during a first time interval and a second multiplier coefficient during a second time interval; and generating the first and second data parts in dependence on the first and second multiplier coefficients respectively.

43. The method of claim 42, further comprising serially receiving a sequence of coefficients.

44. The method of claim 41, further comprising receiving an input data part during a time interval; and multiplying a portion of the input data part by a predetermined coefficient.

45. The method of claim 44, further comprising calculating a linear function of the input data part.

46. The method of claim 45, wherein the linear function has first and second degenerate coefficients and the data part has first and second data portions; the method further comprising calculating the sum of the products of the first data portion and the first degenerate coefficient; and the second data portion and the second degenerate coefficient by adding the first and second data portion and multiplying the result by the value of the degenerate coefficient.

47. The method of claim 41, further comprising directing data in dependence on a control signal.

48. The method of claim 41, further comprising re-ordering data.

49. The method of claim 41, further comprising implementing a downsampling finite impulse response filter.
